(19) United States
(12) Patent Application Publication
(10) Pub. No.: US 2024/0416577 A1
(43) Pub. Date: Dec. 19, 2024

(54) PLANARIZATION APPARATUS, PLANARIZATION METHOD, AND METHOD OF MANUFACTURING ARTICLE

(71) Applicant: CANON KABUSHIKI KAISHA, Tokyo (JP)

(72) Inventor: RYOSUKE TSUTSUMI, Tochigi (JP)

(21) Appl. No.: 18/735,619

(22) Filed: Jun. 6, 2024

(30) Foreign Application Priority Data
Jun. 16, 2023 (JP) 2023-099383

(51) Int. Cl. B29C 59/00; B29C 59/02

(52) U.S. Cl. CPC B29C 59/002; B29C 59/026

(57) ABSTRACT

Provided is a planarization apparatus configured to perform a planarization process of forming a planar layer on a substrate by bringing a planar surface of a template into contact with a curable composition on the substrate and then curing the curable composition, the planarization apparatus including: a transport unit configured to transport the substrate or the template; a first holding unit configured to hold the substrate or the template transported by the transport unit; a second holding unit configured to receive the substrate or the template held by the first holding unit from the first holding unit; and a measuring unit configured to measure a position of the substrate or the template held by the second holding unit in a plane direction, wherein an amount of positional shift is obtained from a reference position of the position measured by the measuring unit.

### BACKGROUND OF THE INVENTION

### Field of the Invention

The present invention relates to a planarization apparatus, a planarization method, a method of manufacturing an article, and the like.

### Description of the Related Art

With the increasing demand for miniaturization of semiconductor devices, in addition to conventional photolithography technology, microfabrication technology of molding and curing an uncured curable composition on a substrate with a mold to form a pattern of the curable composition on the substrate has been attracting attention. Such technology is referred to as imprinting technology, which can form fine patterns on the order of several nanometers on a substrate.

One example of imprinting technology is a photo-curing method. An imprinting device in which the photo-curing method is adopted forms a pattern on a substrate by molding a photocurable composition supplied to a shot region on the substrate with a mold, irradiating the curable composition with light to cure it, and separating the mold from the cured curable composition.

On the other hand, technology of planarization a curable composition on a substrate has also been proposed. Such technology involves forming a planar layer on the substrate by dropping a curable composition on the basis of a stepped difference of the substrate and curing the curable composition in a state where a template having a planar surface is brought into contact with the dropped curable composition.

Such planarization technology requires that the entire surface of the substrate is in contact with the template during a curing process, but if a template larger than the substrate is used, a transport unit for transporting the substrate and a transport unit for transporting the template have to be provided separately. For this reason, it is common to use a template having the same shape and size as the substrate.

If the substrate and the template are the same size, alignment of the substrate and the template is important in order to bring the template into contact with the entire surface of the substrate. Consequently, Japanese Patent Laid-Open No. 2020-43315 proposes a technique of detecting the position of a template held by a template holding unit in a plane direction.

That is, in Japanese Patent Laid-Open No. 2020-43315, since the surface of the template is deformed into a convex shape due to its own weight and atmospheric pressure control, the position of the convex portion is measured with a sensor and controlled so that the convex portion of the template comes into contact with a predetermined region on the substrate.

However, in the planarization technology disclosed in Japanese Patent Laid-Open No. 2020-43315, since the convex portion of the template has a curved shape, it is difficult to specify the position of the tip of the convex portion, and it is not possible to guarantee that the tip of the convex portion is at the center of the template.

For this reason, it is also not possible to guarantee that the center of the template will be aligned with the center of the substrate when the template and the substrate are brought into contact with each other. Since the template and the substrate are the same size, misalignment between the center of the template and the center of the substrate may cause there to be locations on the outer circumferential portion of the substrate which are not in contact with the template, which leads to the possibility of non-planarized regions occurring on the substrate depending on conditions.

### SUMMARY OF THE INVENTION

According to an embodiment of the present invention, there is provided a planarization apparatus configured to perform a planarization process of forming a planar layer on a substrate by bringing a planar surface of a template into contact with a curable composition on the substrate and then curing the curable composition, the planarization apparatus including: a transport unit configured to transport the substrate or the template; a first holding unit configured to hold the substrate or the template transported by the transport unit; a second holding unit configured to receive the substrate or the template held by the first holding unit from the first holding unit; and a measuring unit configured to measure a position of the substrate or the template held by the second holding unit in a plane direction, wherein an amount of positional shift is obtained from a reference position of the position measured by the measuring unit.

Further features of the present invention will become apparent from the following description of embodiments with reference to the attached drawings.

### BRIEF DESCRIPTION OF THE DRAWINGS

FIG. 1 is a diagram illustrating a configuration of a planarization apparatus according to a first embodiment.

FIGS. 2A to 2E are schematic diagrams illustrating a planarization process.

FIGS. 3A to 3D are schematic diagrams illustrating an example of a method of aligning a substrate and a template.

FIGS. 4A to 4D are schematic diagrams illustrating an example of a method of aligning the substrate and the template.

FIGS. 5A and 5B are schematic diagrams illustrating an example of a method of measuring the position of the template on a template holding unit in an XY direction.

FIGS. 6A to 6C are schematic diagrams illustrating a method of correcting a lateral shift.

FIGS. 7A to 7G are schematic diagrams illustrating an example of a method of correcting a positional shift of the template.

FIGS. 8A to 8G are schematic diagrams illustrating an example of a method of correcting a positional shift of the template.

FIG. 9 is a diagram illustrating a configuration of a planarization apparatus according to a second embodiment.

### DESCRIPTION OF THE EMBODIMENTS

Hereinafter, with reference to the accompanying drawings, favorable modes of the present invention will be described using Embodiments. In each diagram, the same reference signs are applied to the same members or elements, and duplicate description will be omitted or simplified.

### <Planarization Apparatus and Planarization Method>

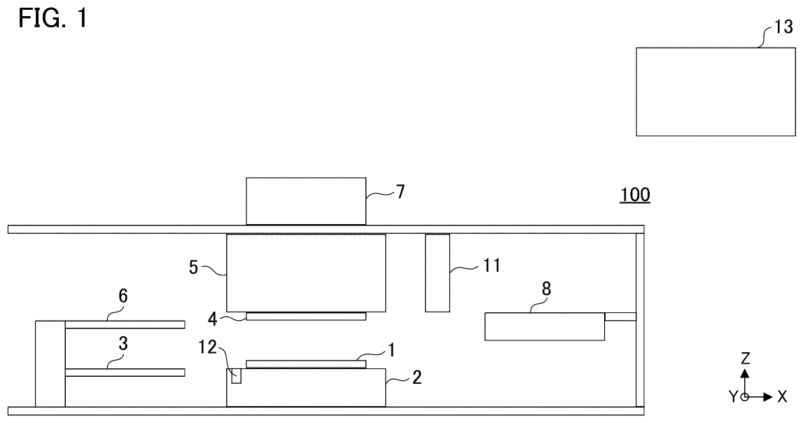

FIG. 1 is a diagram illustrating a configuration of a planarization apparatus 100 according to a first embodiment. FIG. 1 is a diagram of a planarization apparatus viewed in a Y direction. The planarization apparatus 100 is configured to perform a planarization process of forming a planar curable composition on a substrate 1.

Specifically, the planarization apparatus 100 includes a substrate holding unit 2, a template holding unit 5, a substrate transport unit 3, a template transport unit 6, and a control unit 13. The planarization apparatus 100 planarizes a curable composition on the substrate 1 by performing a contact step of bringing a curable composition on the substrate 1 into contact with a template 4, an exposure step of curing the curable composition in contact with the template 4, and a release step of releasing the cured curable composition and the template 4.

In the present specification and the accompanying drawings, directions are indicated in an XYZ coordinate system in which a direction parallel to the surface of the substrate 1 is defined as an XY plane. Alignment means controlling the positions in the XY directions. Alignment can include controlling the position of at least one of the substrate 1 and the template 4 in the Z direction. Here, the XY directions parallel to the surface of the substrate 1 are also referred to as plane directions.

As the curable composition, a curable composition (sometimes referred to as an uncured resin) which is cured by applying energy for curing is used. Examples of the energy for curing to be used include electromagnetic waves, heat, and the like. Examples of electromagnetic waves include light such as infrared rays, visible rays, and ultraviolet rays of which the wavelengths are selected from a range equal to or greater than 10 nm and equal to or less than 1 mm.

The curable composition is applied onto the substrate in the form of a film by a spin coater or a slit coater. Alternatively, the curable composition may be applied onto the substrate by a liquid injection head in the form of droplets or in the form of islands or films formed by connecting a plurality of droplets.

The viscosity (viscosity at 25° C.) of the curable composition is, for example, equal to or greater than 1 mPa-s and equal to or less than 100 mPa-s. The curable composition can be a UV-curable liquid if UV light is used as the energy for curing. The curable composition can be a monomer such as, for example, acrylate or methacrylate.

A typical base material for the substrate 1 is, for example, a silicon wafer, but there is no limitation thereto. The substrate 1 can be arbitrarily selected from among known substrates for semiconductor devices such as aluminum, a titanium-tungsten alloy, an aluminum-silicon alloy, an aluminum-copper-silicon alloy, a silicon oxide, and a silicon nitride. Meanwhile, the substrate 1 typically has, but not limited to, a circular shape having a diameter of 300 mm.

If light is used as energy for curing the curable composition on the substrate 1, the template 4 is composed of a material that transmits the light. The template 4 is composed of, for example, at least one of glass, quartz, a light-transmissive resin such as a polycarbonate resin, and the like.

The template 4 can have, in one example, but is not limited to, a circular shape having a diameter of 300 mm or a circular shape having a diameter greater than 300 mm and smaller than 500 mm. The template 4 includes a planar surface that follows the surface shape of the substrate 1 in contact with the curable composition on the substrate 1. In this case, the planar surface has the same size as the substrate 1 or a larger size than the substrate 1.

The substrate holding unit 2 includes a chuck such as a vacuum chuck or an electrostatic chuck, and holds the substrate 1 with the chuck. The substrate holding unit 2 is driven in the X direction and the Y direction in order to position the substrate 1 held by the substrate holding unit 2 at a predetermined location. In addition, the substrate holding unit 2 may have a function of driving in two or more axial directions (for example, six axial directions of X, Y, Z, Ox, 6y, and 6z).

If the substrate holding unit 2 is driven in the Z direction, it drives toward the template holding unit 5, so that the curable composition on the substrate 1 can be brought into contact with the template 4 and further released from the template 4. In addition, the chuck of the substrate holding unit 2 is provided with, for example, three or more through holes, and has push-up pins which are inserted into and taken out of these through holes. The push-up pins are configured to be able to adsorb the substrate at their tips, and can hold the substrate in a state where the push-up pins are taken out of the chuck.

The template holding unit 5 includes a chuck such as a vacuum chuck or an electrostatic chuck, and holds the template 4 with the chuck. The template holding unit 5 is driven in the Z direction in order to position the template 4 held by the template holding unit 5 at a predetermined location.

In addition, the template holding unit 5 may have a function of driving in one or more axial directions (for example, six axial directions of X, Y, Z, Ox, 6y, and 6z). If the template holding unit 5 is driven in the Z direction, it drives toward the substrate holding unit 2, so that the template 4 can be brought into contact with the curable composition on the substrate 1 and released from the substrate 1.

The substrate transport unit 3 is a transport unit including a transport hand or the like capable of adsorbing and transporting the substrate 1, and the substrate 1 stored in a substrate storage unit (not shown) is carried into the planarization apparatus 100 by the substrate transport unit 3. After the substrate transport unit 3 is driven in front of the substrate holding unit 2, the substrate 1 is transported to the substrate holding unit 2 and positioned and can be held by the chuck of the substrate holding unit 2. In addition, the substrate transport unit 3 can also transport the template 4 having the same shape as the substrate 1.

The template transport unit 6 is a transport unit including a transport hand or the like that can adsorb and transport the template 4, and the template 4 stored in a template storage unit (not shown) is carried into the planarization apparatus 100 by the template transport unit 6.

After the template transport unit 6 is driven in front of the template holding unit 5, the template 4 is transported to the template holding unit 5 and positioned and can be held by the chuck of the template holding unit 5. In addition, the template transport unit 6 can also transport the substrate 1 having the same shape as the template 4. Further, the template transport unit 6 is configured to be able to adjust the position of the template 4 in the XY directions when the template is attached to the template holding unit 5.

In the planarization apparatus 100, the substrate transport unit 3 and the template transport unit 6 are configured as separate transport units, but for reasons such as reducing device costs, they may be configured as one common transport unit that transports both the substrate 1 and the template 4. In this case, the “substrate transport unit 3” and the “template transport unit 6” used in the following description are called a “substrate template transport unit.”

A light source emitting unit 7 is configured to emit light such as, for example, UV light in the Z direction. The light emitted by the light source emitting unit 7 passes through the template holding unit 5 and the template 4 and is radiated onto the uncured curable composition on the substrate 1.

Although the light source emitting unit 7 is disposed so that the light emitted from the light source emitting unit 7 passes through the template holding unit 5 in FIG. 1, it may be configured as a separate unit like a composition application unit 8. In this case, for example, the template 4 is brought into contact with the uncured curable composition on the substrate 1, the template 4 is thereafter released from the template holding unit 5, the substrate holding unit 2 is moved under the light source emitting unit 7 in a state where the template 4 is placed on the substrate 1, and light is emitted from the light source emitting unit 7 to cure the curable composition.

The composition application unit 8 disposes or supplies an uncured (liquid-state) curable composition onto the substrate 1. The composition application unit 8 may include, for example, a discharge port (nozzle) that discharges the curable composition.

The composition application unit 8 supplies a minute volume (for example, 1 picoliter) of curable composition on the substrate 1 using a method such as, for example, a piezojet method or a microsoleroid method.

The number of discharge ports provided in the composition application unit 8 is not limited to a specific number, and may be one or plural. In an example, the composition application unit 8 has 100 or more discharge ports. Such a plurality of discharge ports are disposed, for example, in one or a plurality of lines.

A measuring unit 11 is a component necessary for an embodiment of the present invention. The measuring unit 11 is, for example, a camera that can measure alignment marks on the substrate 1. By sequentially performing movement of the substrate holding unit 2 in the XY directions and image capturing performed by the camera, the positions of a plurality of alignment marks on the substrate 1 in the XY directions are measured, and the position of the substrate 1 in the XYθ directions is specified.

Alternatively, the measuring unit 11 is, for example, a displacement sensor that can detect the distance to the substrate 1. By sequentially performing movement of the substrate holding unit 2 in the XY directions and distance detection performed by the sensor, the positions of a plurality of peripheral edges of the substrate 1 are detected, and the position of the substrate 1 in the XY directions is specified. Although the measuring unit 11 is shown as a separate unit from the template holding unit 5 in FIG. 1, the measuring unit 11 may be included as a component of the template holding unit 5.

A measurement unit 12 is a component necessary for an embodiment of the present invention. The measurement unit 12 is, for example, a displacement sensor that can detect the distance to the template 4. The measurement unit 12 measures the position of the template 4 held by the template 4 in the planarization process.

By sequentially performing movement of the substrate holding unit 2 in the XY directions and distance detection performed by the sensor, the positions of a plurality of peripheral edges of the template 4 are detected, and the position of the template 4 in the XY directions is specified. Alternatively, the measurement unit 12 may be a camera that can measure alignment marks on the substrate 1 held by the template holding unit 5. Although the measurement unit 12 is shown as being integral with the substrate holding unit 2 in FIG. 1, the measurement unit 12 may be a separate component from the substrate holding unit 2.

The control unit 13 is a control unit that controls the operation of each component unit of the planarization apparatus 100 and acquires sensor values, images, and the like. In addition, the control unit 13 calculates the amount of positional shift from a reference position of the position of the substrate 1 or the template 4 in the plane direction.

Further, the control unit 13 adjusts the position of at least one of the template holding unit 5, the substrate holding unit 2, and the template 4 held by the template holding unit 5 in the planarization process on the basis of the amount of positional shift from the reference position of the position of the substrate 1 or the template 4 in the plane direction.

The control unit 13 is constituted by a computer, a sequencer, or the like (not shown) which is connected to each unit of the planarization apparatus 100 through a line, and includes a central processing unit (CPU), a memory (storage unit), and the like.

In addition, the control unit 13 comprehensively controls the operation adjustment or the like of each component of the entire planarization apparatus 100 in accordance with a program stored in the memory. In addition, the control unit 13 may be configured integrally with other parts of the planarization apparatus 100 (in a common housing). Further, it may be configured separately from other parts of the planarization apparatus 100 (in a separate housing), or may be installed at a different location from the planarization apparatus 100 and controlled remotely.

The planarization process executed by the planarization apparatus 100 is a process of molding the curable composition on the substrate 1 and forming a film having a planarized surface using the cured product of the curable composition. That is, the planarization apparatus 100 is a device that performs the planarization process of forming a planar surface on the surface of the substrate 1 by bringing the planar surface of the template 4 into contact with the surface of the substrate 1 to which the curable composition is applied and then curing the curable composition.

More specifically, in the planarization process, the curable composition is planarized by bringing the planar surface of the template 4 into contact with the curable composition on the substrate 1 to make it follow the surface shape of the substrate 1. The planarization process is generally performed on a lot-by-lot basis, that is, on each of a plurality of substrates included in the same lot.

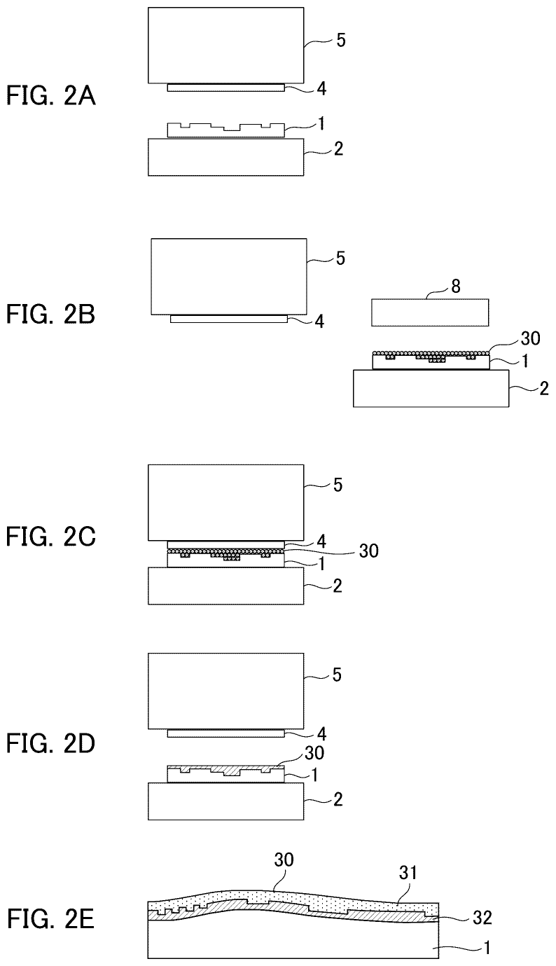

FIG. 2 is a schematic diagram illustrating a planarization process. Here, a description will be given of a planarization process in which a curable composition is dropped onto the entire surface of the substrate 1, the curable composition is brought into contact with the template 4, and the curable composition is planarized. The planarization process is not limited to this, and the curable composition on a partial region of the substrate 1 may be brought into contact with the template 4 to planarize the curable composition.

First, as shown in FIG. 2A, the substrate 1 is held on the substrate holding unit 2, and the template 4 is held on the template holding unit 5. Next, as shown in FIG. 2B, an uncured curable composition 30 is disposed on the substrate 1 on which a base pattern is formed (application step).

Specifically, a curable composition used as a planarization material is dropped onto the substrate 1 by the composition application unit 8. Here, the distribution of the curable composition disposed by the composition application unit 8 may be adjusted in accordance with the shape (stepped difference) of the base pattern formed on the surface of the substrate 1.

Next, as shown in FIG. 2C, the template 4 (also referred to as a superstrate) provided with a planar portion having the same dimensions as the substrate 1 on the substrate 1 is brought into contact with the curable composition 30 on the substrate 1 (contact step). This causes the curable composition 30 to spread and form a film.

Further, in a state where the template 4 is brought into contact with the curable composition 30 on the substrate 1, energy for curing the curable composition 30 is applied to the curable composition by the light source emitting unit 7, and the curable composition 30 is cured (curing step).

Meanwhile, during the curing step, it is necessary that all the planar portions of the template 4 come into contact with the curable composition 30 on the substrate 1 and that the planar portions of the template 4 follow the surface shape of the substrate 1. Light such as ultraviolet rays can be used as the energy for curing used in the curing step.

Finally, as shown in FIG. 2D, the template 4 is separated from the cured curable composition 30 on the substrate 1 (release step). Thereby, a planar layer (planar film) 31 consisting of the cured curable composition 30 remains on the substrate 1. FIG. 2E is an enlarged cross-sectional view of a partial region of the substrate 1 on which a planar layer is formed.

By using the template 4 in this way, the planar layer (planar film) 31 having a locally planar surface can be formed from a cured product of the curable composition. A base pattern 32 on the substrate 1 has an uneven profile caused by the pattern formed in the previous step, and especially with the recent trend toward multi-layered structures of memory elements, some process substrates have a stepped difference of about 100 nm.

In the planarization method as described above, the planar layer can be formed all over the substrate 1 at once by using the template 4 having an area that covers the entirety of a plurality of shot regions of the substrate 1.

### <Method 1 of Aligning Substrate and Template>

Next, one method of alignment in the XY directions during the planarization process in which the substrate 1 and the template 4 are brought into contact with each other in the planarization apparatus 100 will be described. In this method, the substrate 1 transported by transport unit is held by a first holding unit, the substrate 1 held by the first holding unit is transferred from the first holding unit to a second holding unit, and the position of the substrate held by the second holding unit in its plane direction is measured by a measuring unit.

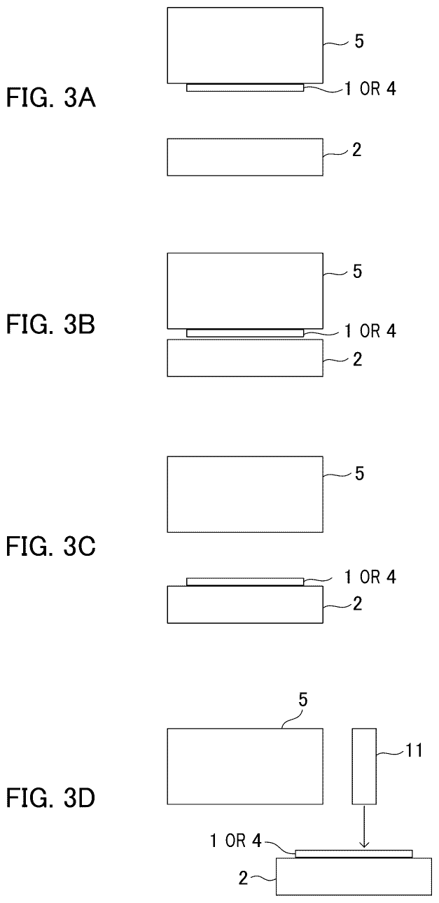

The control unit 13 then calculates the amount of positional shift from the reference position of the substrate 1 measured by the measuring unit. Specifically, this will be described with reference to FIG. 3. Meanwhile, each operation (step) shown in this method can be executed under control of the CPU of the control unit 13.

First, the substrate 1 stored in a substrate storage unit (not shown) is taken out by the template transport unit 6 and then transported to the front of the template holding unit 5 through the same route as a route when the template 4 is transported, and the transported substrate 1 is held by the chuck of the template holding unit 5. That is, in this method, the transport unit is the template transport unit 6, and the first holding unit is the template holding unit 5.

FIG. 3 is a schematic diagram illustrating an example of a method of aligning a substrate and a template. FIG. 3A shows a state in which the substrate 1 is held by the template holding unit 5. Here, the substrate holding unit 2 does not hold the substrate 1 nor does it hold the template 4.

Next, as shown in FIG. 3B, after the template holding unit 5 is driven in the Z direction so as to approach the substrate holding unit 2, the substrate 1 is released from the template holding unit 5 and the substrate 1 is held by the substrate holding unit 2. That is, in this method, the second holding unit is the substrate holding unit 2.

Next, as shown in FIG. 3C, the template holding unit 5 is driven in the Z direction so as to be away from the substrate holding unit 2. Next, as shown in FIG. 3D, the position of the substrate 1 on the substrate holding unit 2 in the XY directions is specified by moving the substrate holding unit 2 under the measuring unit 11 and performing the movement of the substrate holding unit 2 in the XY directions and the measurement performed by the measuring unit 11 multiple times. That is, in this method, the measuring unit is the measuring unit 11.

In the alignment method 1, a reference position is required along with the above measured and specified position of the substrate 1 in order to obtain the positional shift of the substrate 1 transferred from the template holding unit 5 to the substrate holding unit 2. The reference position is determined through a step different from the above.

That is, the substrate 1 stored in the substrate storage unit is first taken out by the substrate transport unit 3 and transported to the front of the substrate holding unit 2 through a route for transporting the substrate 1, and the substrate 1 is held by the substrate holding unit 2.

Thereafter, as shown in FIG. 3D, the position of the substrate 1 on the substrate holding unit 2 in the XY direction is specified by moving the substrate holding unit 2 under the measuring unit 11 and performing the movement of the substrate holding unit 2 in the XY directions and the measurement performed by the measuring unit 11 multiple times. The position of the substrate 1 specified here serves as the reference position.

Here, the above reference position is the position of the substrate 1 in the XY directions in the contact step of bringing the curable composition on the substrate 1 into contact with the template 4. That is, the reference position is the position of the substrate 1, in its plane direction, held by the substrate holding unit 2 which is measured using the measuring unit 11 after the substrate 1 is transported to the substrate holding unit 2 in the planarization process.

The control unit 13 obtains the amount of positional shift from the difference between the position of the substrate 1 transferred from the template holding unit 5 to the substrate holding unit 2 and the above reference position. The amount of positional shift obtained here is the amount of positional shift in the XY directions of the template 4 held by the template holding unit 5 when the template holding unit 5 is driven to a Z position during the planarization process. That is, it is a shift at the XY position of the template 4 with respect to the substrate 1 when the template 4 comes into contact with the substrate 1.

The above positional shift can be caused by the positional shift of the template transport unit 6 in the XY directions when the template 4 is held by the template holding unit 5. Alternatively, it is the positional shift of the template holding unit 5 in the XY directions (lateral shift) which is caused by driving the template holding unit 5 in the Z direction in order to bring the template 4 held by the template holding unit 5 into contact with the substrate 1 on the substrate holding unit 2. Alternatively, it is a positional shift which is a sum of both positional shifts.

In order to accurately superimpose the positions of the substrate 1 and the template 4 in the XY directions during the planarization process, it is necessary to correct the positional shift of the template 4. Thus, the control unit 13 adjusts the positions of the template 4 and the substrate 1 in the plane direction so that they are aligned before the planar surface of the template 4 is brought into contact the surface of the substrate 1 to which the curable composition is applied.

For example, this positional shift is corrected by adjusting the position of the substrate holding unit 2 in the XY directions so that the position of the substrate 1 to which the curable composition held by the substrate holding unit 2 is applied is at a position where the above positional shift is offset.

That is, the control unit 13 adjusts the position of the substrate holding unit 2 in the planarization process on the basis of the obtained amount of positional shift. Alternatively, one correction method is to adjust the position of the template transport unit 6 in the XY directions when the template 4 is transferred to the template holding unit 5 so that the position of the template 4 when the template 4 is held by the template holding unit 5 is at a position where the above positional shift is offset.

That is, the control unit 13 performs adjustment for correcting the amount of positional shift in the plane direction when the template 4 is held by the template holding unit 5 by adjusting the position of the template transport unit 6 in the plane direction when the template 4 is held by the template holding unit 5 from the template transport unit 6.

By performing such adjustment before the planar surface of the template 4 is brought into contact with the surface of the substrate 1 to which the curable composition is applied, it is possible to improve the accuracy of superimposition of the template 4 and the substrate 1 in the contact step and to planarize the entire outer circumferential portion of the substrate.

In addition, if the above positional shift exceeds the allowable amount of shift, the control unit 13 may issue an alert, stop the planarization apparatus 100, perform another step for adjustment, confirm that the positional shift is no longer present, and then restart the planarization apparatus.

According to this method, it is possible to reduce the positional shift of the template 4 held by the template holding unit 5 in the XY directions when the template holding unit 5 is driven to the Z position during the planarization process.

### <Method 2 of Aligning Substrate and Template>

Next, one method of alignment in the XY directions during the planarization process in which the substrate 1 and the template 4 are brought into contact with each other in the planarization apparatus 100 will be further described.

In this method, the template 4 transported by the transport unit is held by the first holding unit, the template 4 held by the first holding unit is transferred from the first holding unit to the second holding unit, and the position of the template 4 held by the second holding unit in the plane direction is measured by the measuring unit.

The control unit 13 then calculates the amount of positional shift from the reference position of the template 4 measured by the measuring unit. Specifically, this will be described with reference to FIG. 3. Meanwhile, each operation (step) shown in this method can be executed under control of the CPU of the control unit 13.

First, the template 4 stored in a template storage unit (not shown) is taken out by the template transport unit 6 and then transported to the front of the template holding unit 5 through a route when the template 4 is transported, and the transported template 4 is held by the chuck of the template holding unit 5. That is, in this method, the transport unit is the template transport unit 6, and the first holding unit is the template holding unit 5.

FIG. 3A shows a state in which the template 4 is held by the template holding unit 5. Here, the substrate holding unit 2 does not hold the substrate 1 nor does it hold the template 4. Next, as shown in FIG. 3B, after the template holding unit 5 is driven in the Z direction so as to approach the substrate holding unit 2, the template 4 is released from the template holding unit 5 and the template 4 is held by the substrate holding unit 2.

That is, in this method, the second holding unit is the substrate holding unit 2. Next, as shown in FIG. 3C, the template holding unit 5 is driven in the Z direction so as to be away from the substrate holding unit 2. Next, as shown in FIG. 3D, the position of the template 4 on the substrate holding unit 2 in the XY directions is specified by moving the substrate holding unit 2 under the measuring unit 11 and performing the movement of the substrate holding unit 2 in the XY directions and the measurement performed by the measuring unit 11 multiple times. That is, in this method, the measuring unit is the measuring unit 11.

Here, the upper surface of the template 4 is the surface which is held by the chuck of the template holding unit 5. On the other hand, since the lower surface of the template 4 is a planar surface that contacts the curable composition on the substrate 1 and follows the surface shape of the substrate 1, and the flatness accuracy of the planar surface needs to be maintained, it is preferable that the lower surface of the template 4 is not held by the chuck of the substrate holding unit 2.

Consequently, when the template 4 is transferred from the template holding unit 5 to the substrate holding unit 2, a push-up pin is taken out of the through hole of the substrate holding unit 2, the template 4 is transferred onto the push-up pin, and then the template 4 is held by the push-up pin. In a state where the template 4 is held by the push-up pin, the substrate holding unit 2 is moved under the measuring unit 11 to measure the position of the template 4.

The above step of measuring the position of the template 4 and specifying the positional shift may be performed each time the template 4 held by the template holding unit 5 is replaced with a new template. In this case, since it is necessary that the substrate 1 is not held on the substrate holding unit 2, it is preferable to perform the above step of specifying the positional shift when the template 4 is replaced at the break between lots, that is, at the head of the lot.

In other words, in a case in which the planarization process is performed on a plurality of substrates 1 under the same conditions, it is preferable that the control unit 13 obtains the positional shift before, preferably immediately before, the planarization process is performed on a first substrate that undergoes the planarization process as a first one of the plurality of substrates.

Here, the reference position for obtaining the positional shift of the template 4 transferred from the template holding unit 5 to the substrate holding unit 2 is obtained using the same method as the above alignment method 1. In addition, a method for aligning the positions of the substrate 1 and the template 4 in the XY directions during the planarization process is the same as the above alignment method 1.

According to this method, it is possible to reduce the positional shift of the template 4 held by the template holding unit 5 in the XY directions when the template holding unit 5 is driven to the Z position during the planarization process.

### <Method 3 of Aligning Substrate and Template>

Next, one method of alignment in the XY directions during the planarization process in which the substrate 1 and the template 4 are brought into contact with each other in the planarization apparatus 100 will be described.

In this method, the substrate 1 transported by the transport unit is held by the first holding unit, the substrate 1 held by the first holding unit is transferred from the first holding unit to the second holding unit, and the position of the substrate 1 held by the second holding unit in the plane direction is measured by the measuring unit.

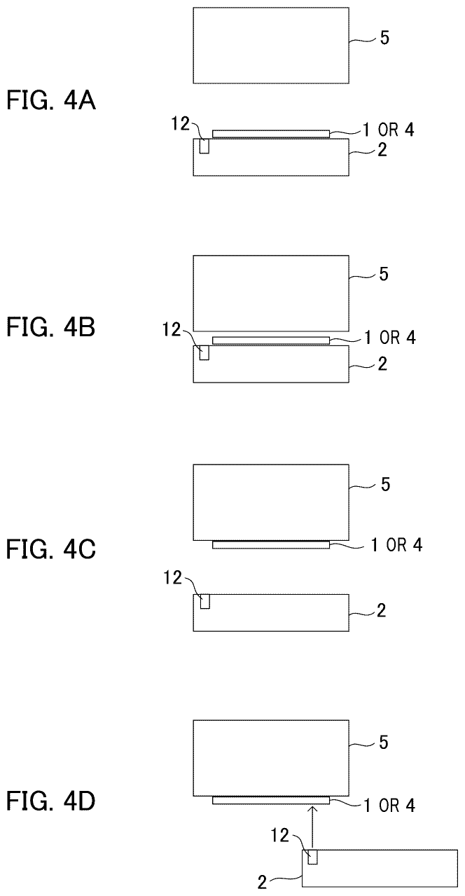

The control unit 13 then calculates the amount of positional shift from the reference position of the substrate 1 measured by the measuring unit. Specifically, this will be described with reference to FIG. 4. Meanwhile, each operation (step) shown in this method can be executed under control of the CPU of the control unit 13.

First, the substrate 1 stored in the substrate storage unit is taken out by the substrate transport unit 3 and then transported to the front of the substrate holding unit 2 through a route when the substrate 1 is transported, and the transported substrate 1 is held by the chuck of the substrate holding unit 2. That is, in this method, the transport unit is the substrate transport unit 3, and the first holding unit is the substrate holding unit 2.

FIG. 4 is a schematic diagram illustrating an example of a method of aligning a substrate and a template. FIG. 4A shows a state in which the substrate 1 is held by the substrate holding unit 2. Here, the template holding unit 5 does not hold the substrate 1 nor does it hold the template 4. In addition, the curable composition is not applied onto the substrate 1 held by the substrate holding unit 2.

Next, as shown in FIG. 4B, after the template holding unit 5 is driven to the Z direction so as to approach the substrate holding unit 2, the holding of the substrate 1 is released from the substrate holding unit 2, adsorption control is performed on the chuck of the template holding unit 5, and the substrate 1 is held by the template holding unit 5. That is, in this method, the second holding unit is the template holding unit 5.

Next, as shown in FIG. 4C, the template holding unit 5 is driven in the Z direction so as to be away from the substrate holding unit 2. Next, as shown in FIG. 4D, the position of the substrate 1 on the template holding unit 5 in the XY directions is specified by moving the substrate holding unit 2 to a position where the substrate 1 can be measured by the measurement unit 12 and performing the movement of the substrate holding unit 2 in the XY directions and the measurement performed by the measurement unit 12 multiple times. That is, in this method, the measuring unit is the measurement unit 12.

In the alignment method 3, a reference position is required along with the above measured and specified position of the substrate 1 in order to obtain the positional shift of the substrate 1 transferred from the substrate holding unit 2 to the template holding unit 5.

The reference position is determined through a step different from the above. That is, first, the template 4 stored in the template storage unit is taken out by the template transport unit 6 and transported to the front of the template holding unit 5 through a route for transporting the template 4, and the template 4 is held by the template holding unit 5.

The position of the template holding unit 5 in the Z direction is moved to the same Z position as in FIG. 4C where the positional shift of the substrate 1 is measured. Thereafter, as shown in FIG. 4D, the position of the template 4 on the template holding unit 5 in the XY directions is specified by performing the movement of the substrate holding unit 2 in the XY directions and the measurement performed by the measurement unit 12 multiple times.

The position of the template 4 specified here serves as the reference position. In other words, the reference position is the position of the template 4 held by the template holding unit 5 in the plane direction which is measured using the measurement unit 12 after the template 4 is transported to the template holding unit 5 in the planarization process.

The control unit 13 obtains the amount of positional shift from the difference between the position of the substrate 1 transferred from the substrate holding unit 2 to the template holding unit 5 and the above reference position. Here, the obtained positional shift is equivalent to the positional shift of the substrate 1 in the XY directions with respect to the template 4 during the planarization process in which the substrate 1 and the template 4 are brought into contact with each other.

The above positional shift can be caused by the positional shift of the substrate holding unit 2 in the XY directions during the planarization process in which the substrate 1 and the template 4 are brought into contact with each other. Alternatively, it is the positional shift of the template holding unit 5 in the XY directions (lateral shift) which is caused by driving the template holding unit 5 in the Z direction in order to bring the template 4 held by the template holding unit 5 into contact with the substrate 1 on the substrate holding unit 2. Alternatively, it is a positional shift which is a sum of both positional shifts.

In order to accurately superimpose the positions of the substrate 1 and the template 4 in the XY directions during the planarization process, it is necessary to correct the positional shift of the substrate 1. For example, during the planarization process in which the substrate 1 and the template 4 are brought into contact with each other, this positional shift is corrected by adjusting the position of the substrate holding unit 2 in the XY directions so that the position of the substrate 1 to which the curable composition held on the substrate holding unit 2 is applied is at a position where the above positional shift is offset.

That is, the control unit 13 adjusts the position of the substrate holding unit 2 in the planarization process on the basis of the obtained amount of positional shift. In addition, if the above positional shift exceeds the allowable amount of shift, the control unit 13 may issue an alert, stop the planarization apparatus, perform another step for adjustment, confirm that the positional shift is no longer present, and then restart the planarization apparatus 100.

Since the above step of measuring the position of the substrate 1 and specifying the positional shift requires that the curable composition is not applied onto the substrate 1, it is preferable to use a pilot substrate for measurement rather than a lot substrate that undergoes the planarization process.

It is preferable to carry in the pilot substrate before the carrying in the substrate in the lot at the break between lots, that is, at the head of the lot, and to perform the above step of specifying the positional shift. Here, the pilot substrate is a substrate having the same shape and size as the substrate 1.

According to this method, it is possible to reduce the positional shift of the substrate 1 in the XY directions with respect to the template 4 during the planarization process in which the curable composition on the substrate 1 and the template 4 are brought into contact with each other.

### <Method 4 of Aligning Substrate and Template>

Next, one method of alignment in the XY directions during the planarization process in which the substrate 1 and the template 4 are brought into contact with each other in the planarization apparatus 100 will be further described. In this method, the template 4 transported by the transport unit is held by the first holding unit, the template 4 held by the first holding unit is transferred from the first holding unit to the second holding unit, and the position of the template 4 held by the second holding unit in the plane direction is measured by the measuring unit.

The control unit 13 then calculates the amount of positional shift from the reference position of the template 4 measured by the measuring unit. Specifically, this will be described with reference to FIG. 4. Meanwhile, each operation (step) shown in this method can be executed under control of the CPU of the control unit 13.

First, the template 4 stored in the template storage unit is taken out by the substrate transport unit 3 and then transported to the front of the substrate holding unit 2 through the same route as when the substrate 1 is transported, and the transported template 4 is held by the substrate holding unit 2. That is, in this method, the transport unit is the substrate transport unit 3, and the first holding unit is the substrate holding unit 2.

Here, since the lower surface of the template 4 facing the substrate holding unit 2 is a planar surface for creating a planar layer on the substrate 1, it is preferable to hold the template 4 using a push-up pin taken out of the through hole of the chuck rather than holding the chuck of the substrate holding unit 2. Alternatively, if the pilot template is not used to create a planar layer on the substrate 1, it may be held by the chuck of the substrate holding unit 2. Here, the pilot template is a template having the same shape and size as the template 4.

FIG. 4A shows a state in which the template 4 is held by the substrate holding unit 2. Here, the template holding unit 5 does not hold the substrate 1 nor does it hold the template 4. Next, as shown in FIG. 4B, after the template holding unit 5 is driven to the Z direction so as to approach the substrate holding unit 2, the holding of the template 4 is released from the substrate holding unit 2, adsorption control is performed on the chuck of the template holding unit 5, and the template 4 is held by the template holding unit 5.

That is, in this method, the second holding unit is the template holding unit 5. Next, as shown in FIG. 4C, the template holding unit 5 is driven in the Z direction so as to be away from the substrate holding unit 2. Next, as shown in FIG. 4D, the position of the template 4 on the template holding unit 5 in the XY directions is specified by moving the substrate holding unit 2 to a position where the template 4 can be measured by the measurement unit 12 and performing the movement of the substrate holding unit 2 in the XY directions and the measurement performed by the measurement unit 12 multiple times. That is, in this method, the measuring unit is the measurement unit 12.

Here, the reference position for obtaining the positional shift of the template 4 transferred from the substrate holding unit 2 to the template holding unit 5 is obtained using the same method as the above alignment method 3. In addition, a method for aligning the positions of the substrate 1 and the template 4 in the XY directions during the planarization process is the same as the above alignment method 3.

According to this method, it is possible to reduce the positional shift of the substrate 1 in the XY directions with respect to the template 4 during the planarization process in which the curable composition on the substrate 1 and the template 4 are brought into contact with each other.

### <Method 5 of Aligning Substrate and Template>

Next, one method of alignment in the XY directions during the planarization process in which the substrate 1 and the template 4 are brought into contact with each other in the planarization apparatus 100 will be described.

In this method, the template 4 transported by the transport unit is held by the first holding unit, the template 4 held by the first holding unit is transferred from the first holding unit to the second holding unit, and the position of the template 4 held by the second holding unit in the plane direction is measured by the measuring unit.

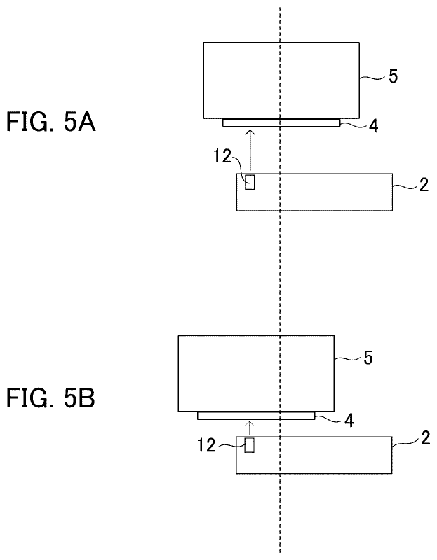

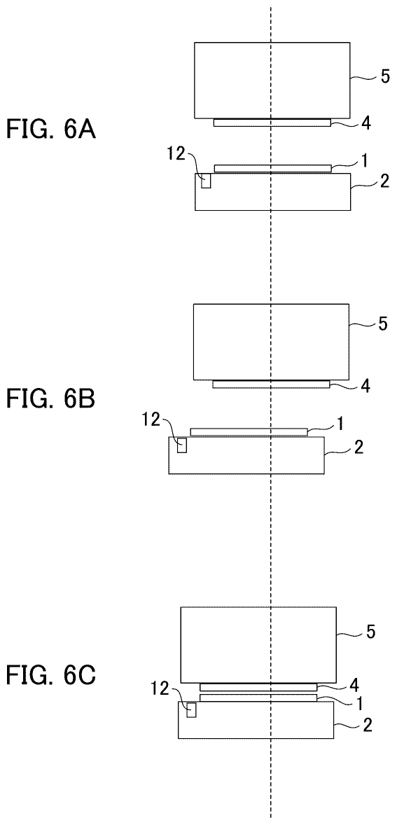

The control unit 13 then calculates the amount of positional shift from the reference position of the template 4 measured by the measuring unit. Specifically, this will be described with reference to FIGS. 5 and 6. Meanwhile, each operation (step) shown in this method can be executed under control of the CPU of the control unit 13.

The planarization apparatus 100 in the alignment method 5 includes the measurement unit 12 that can measure the position of the template 4 held by the template holding unit 5 in the plane direction during the planarization process.

First, the template 4 stored in the template storage unit is taken out by the template transport unit 6 and then transported to the front of the template holding unit 5 through a route for transporting the template 4, and the transported template 4 is held by the template holding unit 5.

FIG. 5 is a schematic diagram illustrating an example of a method of measuring the position of the template 4 on the template holding unit 5 in the XY directions. FIG. 5A shows a state in which the template 4 is held by the template holding unit 5. Here, although it is preferable that the substrate 1 is not held by the substrate holding unit 2, the substrate 1 may be held by the substrate holding unit 2.

Further, as shown in FIG. 5A, the Z position of the template holding unit 5 is located at a longer distance from the substrate holding unit 2 than a predetermined distance, and the movement of the substrate holding unit 2 in the XY directions and the measurement performed by the measurement unit 12 are performed multiple times.

The position of the template 4 on the template holding unit 5 in the XY directions is specified through this measurement. Here, the Z position of the template holding unit 5 is referred to as a Z position before Z drive, and the specified XY position is referred to as an XY position before Z drive.

Next, as shown in FIG. 5B, the Z position of the template holding unit 5 is located at a short distance position closer to the substrate holding unit 2 than the predetermined distance. Similarly to the above, the position of the template 4 on the template holding unit 5 in the XY directions is specified by performing the movement of the substrate holding unit 2 in the XY directions and the measurement performed by the measurement unit 12 multiple times. Regarding each position here, the Z position of the template holding unit 5 is referred to as a Z position after Z drive, and the specified XY position is referred to as an XY position after Z drive.

The control unit 13 obtains the amount of positional shift of the template holding unit 5 in the plane direction in the contact step on the basis of the result of measurement of the measurement unit 12. Specifically, here, the Z position before Z drive is defined as Z1, the XY position before Z drive is defined as XY1, the Z position after Z drive is defined as Z2, the XY position after Z drive is defined as XY2, and the Z position of the template holding unit 5 during the planarization process in which the template 4 is brought into contact with the curable composition on the substrate 1 is defined as Z3.

That is, Z3 is the Z position of the template holding unit 5 in a state where the template 4 is brought into contact with the curable composition on the substrate 1. In this case, the positional shift (lateral shift) XY of the template holding unit 5 in the XY directions when the template holding unit 5 is at the Z position of Z3 is calculated using, for example, the following expression.

$$Positional shift XY = ( \frac{XY 1 - XY 2}{Z 1 - Z 2} ) \times Z 3 + ( \frac{XY 1 \times Z 2 - XY 2 \times Z 1}{Z 2 - Z 1} )$$

As described in the above alignment method 1 described with reference to FIG. 3, the positional shift of the substrate 1 transferred from the template holding unit 5 to the substrate holding unit 2 in the XY direction can be considered to be a combination of several positional shifts.

Alternatively, as described in the above alignment method 2 which has also been described with reference to FIG. 3, the positional shift of the template 4 transferred from the template holding unit 5 to the substrate holding unit 2 in the XY directions can be considered to be a combination of several positional shifts. For example, it can be considered to be the sum of the XY positional shift (holding shift) of the template 4 held on the template holding unit 5 and the XY positional shift (lateral shift) of the template holding unit 5 during Z drive of the template holding unit 5.

Consequently, first, the control unit 13 obtains the amount of XY positional shift of the substrate 1 or the template 4 on the substrate holding unit 2 using the alignment method 1 or the alignment method 2. The difference between the amount of positional shift and the amount of positional shift XY of the template holding unit 5 when the Z position of the template holding unit 5 is at the position of Z3 where the template 4 is brought into contact with the substrate 1 is obtained.

This difference is equivalent to the XY positional shift of the template 4 which is transported and held by the template holding unit 5. Therefore, the control unit 13 uses this difference to adjust the position of the template transport unit 6 in the XY directions when the template 4 is attached to the template holding unit 5 so that the position of the template 4 when the template 4 is attached to the template holding unit 5 is set to a position for offsetting the above difference.

FIG. 6 is a schematic diagram illustrating a method of correcting lateral shift. FIG. 6A shows a state in which the XY position of the template transport unit 6 when the template 4 is attached to the template holding unit 5 is adjusted, and there is no shift in the position of the template 4 on the template holding unit 5 in the XY directions.

Further, the XY position of the substrate holding unit 2 is a position where the template 4 on the template holding unit 5 and the substrate 1 on the substrate holding unit 2 are aligned in the XY directions in a state where the template 4 and the substrate 1 are separated from each other. In this state, when the template holding unit 5 is Z-driven so that the template 4 comes into contact with the substrate 1, the XY positions of the template 4 and the substrate 1 are shifted by the amount of positional shift in the XY directions caused by the Z drive of the template holding unit 5.

Consequently, as shown in FIG. 6B, the substrate holding unit 2 is moved in advance to the XY position of the template holding unit 5 when it is at the position of Z3 where the template 4 and the curable composition on the substrate 1 are brought into contact with each other. Thereafter, as shown in FIG. 6C, the template holding unit 5 is driven to the Z position of Z3 where the template 4 and the substrate 1 are brought into contact with each other, and the planarization process is performed on the curable composition on the substrate 1.

Meanwhile, the amount of XY positional shift of the substrate 1 on the substrate holding unit 2 or the template 4 may be obtained using the alignment method 3 or the alignment method 4, and the difference between the amounts of positional shift may be used.

According to this method, it is possible to correct the positional shift between the template 4 and the substrate 1 in the XY direction caused by the Z drive of the template holding unit 5 in the planarization process.

### <Method 1 of Correcting Positional Shift of Template>

In the planarization process, the same template 4 is generally used for a plurality of substrates 1, and is replaced with a new template 4, for example, at the break between lots, that is, at the head of the lot.

Therefore, it can be considered that the position of the template 4 with respect to the template holding unit 5 does not change within a lot. However, after the template 4 is brought into contact with the substrate 1 and the curable composition on the substrate 1 is planarized and cured, the template 4 and the substrate 1 are stuck together with a large force.

If the template 4 and the substrate 1 are separated from each other by the Z drive of the template holding unit 5 in this state, a large force will be applied to the template 4, which may cause the position of the template 4 to shift on the template holding unit 5.

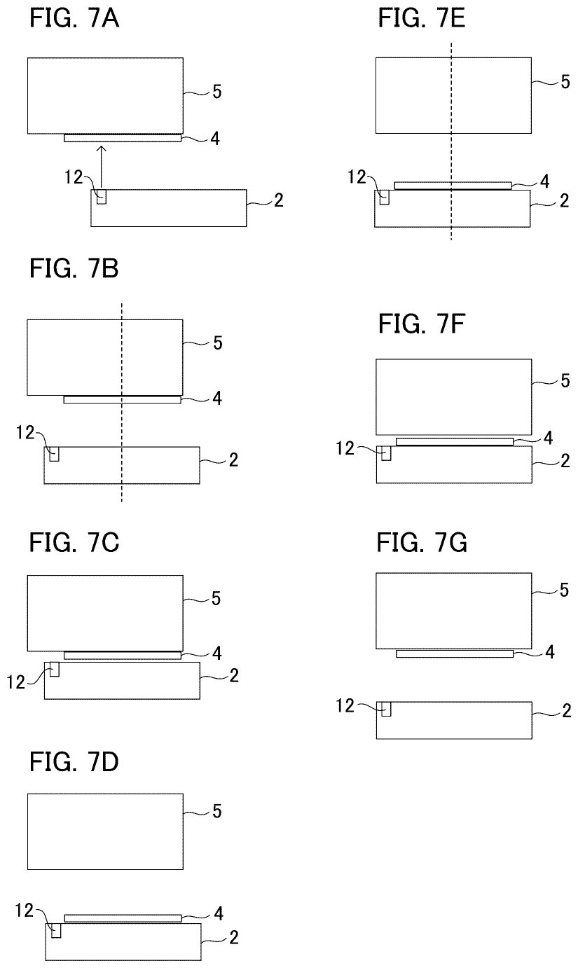

FIG. 7 is a schematic diagram illustrating an example of a method of correcting the positional shift of the template. FIG. 7A shows, for example, a state in which the position of the template 4 on the template holding unit 5 in the XY directions is shifted after the planarization process is performed on the plurality of substrates 1.

In order to detect this positional shift of the template 4, a step of confirming the current position of the template 4 is performed after the planarization process is performed on one substrate 1 (after mold release) or after the planarization process is performed on the plurality of substrates 1.

Similarly, as shown in FIG. 7A, the step of confirming the position of the template 4 includes specifying the current position of the template 4 held by the template holding unit 5 in the XY direction by performing the movement of the substrate holding unit 2 in the XY directions and the measurement performed by the measurement unit 12 multiple times.

The control unit 13 then obtains the amount of positional shift from the reference position of the position of the template 4 on the template holding unit 5 which is measured by the measurement unit 12. Here, if the position of the template 4 is shifted with respect to the reference position, a step of correcting the positional shift of the template 4 is further performed, and the position of the template 4 is returned to the same position as the reference position.

Since this step of correcting the positional shift includes a step of transferring the template 4 to the substrate holding unit 2, it is preferable that the substrate 1 is not placed on the substrate holding unit 2, but the substrate 1 may be placed on the substrate holding unit 2.

In the step of correcting the positional shift of the template 4, the substrate holding unit 2 is first moved from the template holding unit 5 to a first position for receiving the template 4. Specifically, in this method, as shown in FIG. 7B, the substrate holding unit 2 is moved to the same XY position as the current position of the template 4 specified by the measurement unit 12.

That is, the substrate holding unit 2 is moved in the XY directions so as to match the position of the template 4 shifted from the reference position. In this method, the first position is a position where the position of the template 4 held by the template holding unit 5 in the plane direction matches the substrate holding unit 2.

Next, as shown in FIG. 7C, the template holding unit 5 and the substrate holding unit 2 are brought close to each other through the Z drive, the template 4 is released from the template holding unit 5 at the Z position where the template 4 can be transferred to the substrate holding unit 2, and the template 4 is held by the substrate holding unit 2.

Here, since the lower surface of the template 4 facing the substrate holding unit 2 is a planar surface, it is preferable that the template 4 is held by a push-up pin rather than the chuck of the substrate holding unit 2. Alternatively, if the substrate 1 is placed on the substrate holding unit 2, the template 4 is transferred onto the substrate 1.

Next, as shown in FIG. 7D, the Z drive is performed in a direction in which the template holding unit 5 and the substrate holding unit 2 are separated from each other. In this separation operation, there is no need to make a large distance between the template holding unit 5 and the substrate holding unit 2. From the viewpoint of shortening processing time, it is also preferable to perform the Z drive only to the extent that the template holding unit 5 and the template 4 on the substrate holding unit 2 do not come into contact with each other.

Next, the substrate holding unit 2 is moved to a second position for transferring the template 4 to the template holding unit 5. Specifically, in this method, as shown in FIG. 7E, the substrate holding unit 2 is moved to an XY position where the XY positions of the template holding unit 5 and the template 4 on the substrate holding unit 2 match. That is, the substrate holding unit 2 is moved in the XY directions so that the template 4 is aligned with the reference position XY.

If the template 4 is placed on the substrate 1 on the substrate holding unit 2, an inertial force caused by the XY movement of the substrate holding unit 2 acts, and the XY position of the template 4 on the substrate 1 may shift. In this case, the shift of the template 4 on the substrate 1 is suppressed by slowing down the speed of acceleration and deceleration during the XY movement of the substrate holding unit 2.

In this method, the second position is a position where the position of the template 4 held by the substrate holding unit 2 in the plane direction matches the reference position of the template. Next, as shown in FIG. 7F, the template holding unit 5 and the substrate holding unit 2 are brought close to each other through the Z drive, the template 4 is released from the substrate holding unit 2 at the Z position where the template 4 can be transferred to the template holding unit 5, and the template 4 is held by the template holding unit 5. Finally, as shown in FIG. 7G, the Z drive is performed in a direction in which the template holding unit 5 and the substrate holding unit 2 are separated from each other.

By performing a series of processes described with reference to FIG. 7 in this way, even if the XY position of the template 4 on the template holding unit 5 is shifted, the position of the template 4 can be re-held at the correct position (reference position) on the template holding unit 5.

Meanwhile, here, the reference position of the template 4 on the template holding unit 5 is the XY position of the template 4 when the planarization process is performed on the substrate 1, and the reference position is determined using one of the methods to be described below.

One method of determining the reference position is a step which is performed when a new template 4 is held on the template holding unit 5 (template replacement), and includes specifying the XY position of a new template 4 held by the template holding unit 5 by the XY movement of the substrate holding unit 2 and measurement performed by the measurement unit 12.

That is, the reference position which is determined using this method is the position of the template 4 held by the template holding unit 5 in the plane direction which is measured using the measurement unit 12 after the template is held by the template holding unit 5 and before the template 4 is used for the planarization process.

The XY position of the template 4 specified here serves as the reference position. Meanwhile, the XY position of the template transport unit 6 when the template 4 is attached by the template holding unit 5 is corrected in advance, and the template 4 is attached to the correct position (position for the planarization process) of the template holding unit 5.

One method of determining the reference position is a step which is performed when a new template 4 is held on the template holding unit 5 (template replacement), and is a step which is further performed after an old template 4 is removed from the template holding unit 5 and before a new template 4 is attached to the template holding unit 5.

In this step, for example, a pilot substrate for adjustment different from the substrate 1 of the lot is used. After the substrate 1 is transported to the substrate holding unit 2, the substrate 1 is transferred to the template holding unit 5, and the XY position of the substrate 1 held by the template holding unit 5 is specified by the XY movement of the substrate holding unit 2 and measurement performed by the measurement unit 12.

That is, the reference position which is determined using this method is the position of the substrate 1 on the template holding unit 5 in the plane direction which is measured using the measurement unit 12 after the substrate 1 on the substrate holding unit 2 is transferred to the template holding unit 5 in a state where the template 4 is not held by the template holding unit 5. The XY position of the substrate 1 specified here serves as the reference position.

Such a method of correcting the positional shift of the template is performed after the positional shift of the template 4 occurs and is detected for some reason such as after the position of the template 4 is shifted on the template holding unit 5 due to the release step in the planarization process.

According to the above, even if the positional shift of the template 4 occurs in the planarization process, it is possible to improve the accuracy of superimposition of the template and the substrate.

### <Method 2 of Correcting Positional Shift of Template>

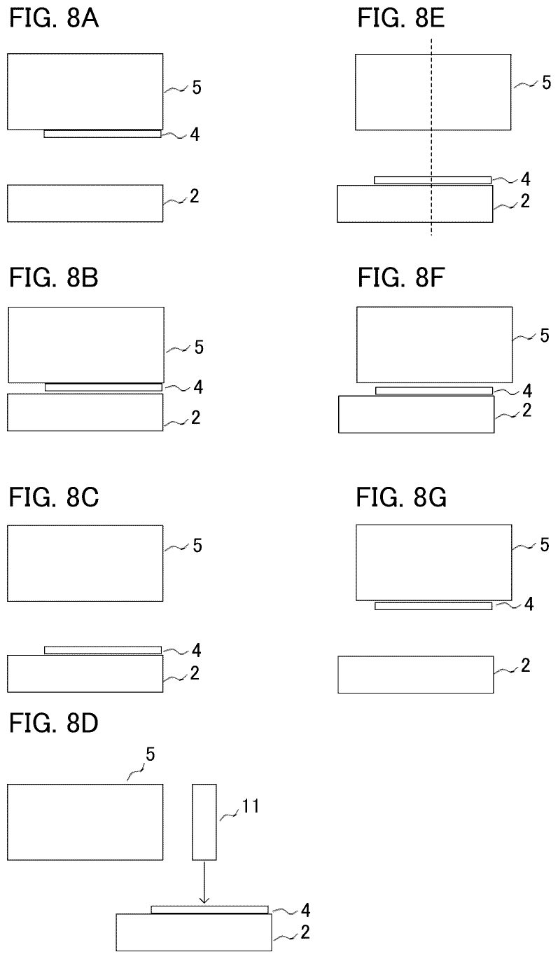

FIG. 8 is a schematic diagram illustrating an example of a method of correcting the positional shift of the template. FIG. 8A shows the same state as the template 4 described with reference to FIG. 7A above, that is, the template 4 is held at a position shifted from the reference position of the template holding unit 5.

A method 2 of correcting the positional shift of the template, which is different from the method 1 of correcting the positional shift of the template, for returning the position of the template 4 to the reference position when the position of the template 4 is shifted in this way will be described.

Although it is preferable that the substrate 1 is not placed on the substrate holding unit 2, the substrate 1 may be placed on the substrate holding unit 2. Next, as shown in FIG. 8B, the template holding unit 5 and the substrate holding unit 2 are brought close to each other through the Z drive, the template 4 is released from the template holding unit 5 at the Z position where the template 4 can be transferred to the substrate holding unit 2, and the template 4 is held by the substrate holding unit 2.

In this method, the first position is a position where the template holding unit 5 and the substrate holding unit 2 are aligned. Here, since the lower surface of the template 4 facing the substrate holding unit 2 is a planar surface, it is preferable that the template 4 is held by a push-up pin rather than the chuck of the substrate holding unit 2. Alternatively, if the substrate 1 is placed on the substrate holding unit 2, the template 4 is transferred onto the substrate 1.

Next, as shown in FIG. 8C, the Z drive is performed in a direction in which the template holding unit 5 and the substrate holding unit 2 are separated from each other. Thereafter, as shown in FIG. 8D, the position of the template 4 on the substrate holding unit 2 in the XY direction is specified by moving the substrate holding unit 2 to a position facing the measuring unit 11 and performing the movement of the substrate holding unit 2 in the XY directions and measurement performed by the measuring unit 11 multiple times.

Here, if the position of the template 4 is shifted with respect to the reference position, the template 4 is returned to the template holding unit 5 after a step of correcting the positional shift of the template 4.

In the step of correcting the positional shift of the template 4, first, as shown in FIG. 8E, the position of the substrate holding unit 2 in the XY direction is moved so that the position of the template 4 specified by the measuring unit 11 is set to the same XY position as the reference position of the template holding unit 5.

That is, in this method, the second position is a position where the position of the template 4 held by the substrate holding unit 2 in the plane direction matches the reference position. Next, as shown in FIG. 8F, the template holding unit 5 and the substrate holding unit 2 are brought close to each other through the Z drive, the template 4 is released from the substrate holding unit 2 at the Z position where the template 4 can be transferred to the template holding unit 5, and the template 4 is held by the template holding unit 5. Finally, as shown in FIG. 8G, the Z drive is performed in a direction in which the template holding unit 5 and the substrate holding unit 2 are separated from each other.

By performing a series of processes described with reference to FIG. 8 in this way, even if the XY position of the template 4 on the template holding unit 5 is shifted, the position of the template 4 can be re-held at the correct position (reference position) on the template holding unit 5.

Here, the reference position of the template 4 on the template holding unit 5 is the XY position of the template 4 when the planarization process is performed on the substrate 1, and the reference position is determined using one of the methods to be described below.

In one method of determining the reference position, for example, a pilot substrate for adjustment different from the substrate 1 within the lot is transported and held on the substrate holding unit 2, and then the XY position of the substrate 1 held by the substrate holding unit 2 is specified by the XY movement of the substrate holding unit 2 and measurement performed by the measuring unit 11.

The XY position of the substrate 1 specified here serves as the reference position. That is, the XY position of the substrate 1 on the substrate holding unit 2 when the substrate holding unit 2 is at the XY position during the planarization process serves as the reference position. In other words, the reference position which is determined using this method is a position of the substrate 1 on the substrate holding unit 2 in the plane direction which is measured using the measuring unit 11 after the substrate 1 is held by the substrate holding unit 2 and before the planarization process is performed on the substrate.

In one method of determining the reference position, the template 4 is transported to the template holding unit 5, the template 4 is thereafter transferred to the substrate holding unit 2, and the XY position of the template 4 held by the substrate holding unit 2 is specified by the XY movement of the substrate holding unit 2 and measurement performed by the measuring unit 11.

In other words, the template 4 is first held by the template holding unit 5 in a state where the substrate 1 is not held by the substrate holding unit 2, and the template 4 is transferred to the substrate holding unit 2. Thereafter, it is the position of the template 4 on the substrate holding unit 2 in the plane direction which is measured using the measuring unit 11. The XY position of the template 4 specified here serves as the reference position.

### <Planarization Apparatus Having Different Configuration and Alignment Method>

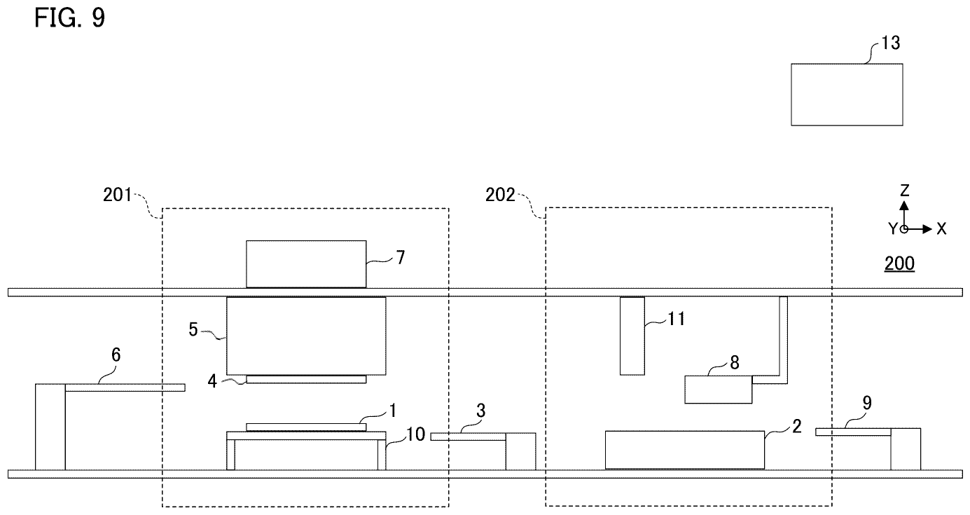

FIG. 9 is a diagram illustrating a configuration of a planarization apparatus 200 according to a second embodiment. The planarization apparatus 200 shown in FIG. 9 is a planarization apparatus having a partially different configuration from the planarization apparatus 100 described in FIG. 1.

The planarization apparatus 200 is characterized in that it is divided into a first station 201 for bringing the template 4 and the substrate 1 into contact with each other and performing the planarization process and a second station 202 for applying the curable composition onto the substrate 1.

The planarization step of creating a curable composition on the substrate 1 as a planar layer requires time because when the template 4 is brought into contact with the substrate 1, curing is started after waiting for the curable composition to spread over the entire surface of the substrate.

On the other hand, the step of applying the curable composition onto the substrate 1 does not require as much time as the planarization step. Therefore, in FIG. 9, only the first station 201 is shown as a station for the planarization process, but processing capacity for the substrate, that is, productivity, is improved by configuring a plurality of stations similar to the first station 201.

In such a configuration, the substrate holding unit for holding the substrate 1 at the first station 201 for the planarization process does not need to move in the XY directions. Therefore, as shown in FIG. 9, it may be configured, for example, with a stand capable of holding the substrate 1, that is, a substrate holding stand 10. On the other hand, at the second station 202 for applying the curable composition, the substrate holding unit 2 is configured to be able to move in the XY direction in order to apply the curable composition to the entire area on the substrate 1.

Further, the substrate transport unit 3 is disposed so that the substrate 1 can be transferred and transported between the first station 201 and the second station 202. In addition, the transport unit that extracts the substrate 1 from the substrate storage unit and transports the substrate 1 to the substrate holding unit 2 of the second station 202 may be configured as a substrate transport unit 9 which is separate from the substrate transport unit 3.

In addition, the transport unit that collects the planarized substrate 1 from above the substrate holding stand 10 of the first station 201 and returns it to the substrate storage unit may be configured as a substrate transport unit (not shown) which is separate from the substrate transport unit 3 and the substrate transport unit 9.

In addition, in the planarization apparatus 200 shown in FIG. 9, the measuring unit 11 for measuring the position of the substrate 1 or the template 4 in the XY directions (position in the plane direction) is disposed at the second station 202.

The flow of the planarization process using this planarization apparatus 200 includes causing the substrate holding unit 2 to hold the substrate 1 transported to the second station 202 by the substrate transport unit 9, measuring the position of the substrate 1 using the measuring unit 11, and applying the curable composition onto the substrate 1 using the composition application unit 8.

Thereafter, the substrate 1 is transported to the first station 201 by the substrate transport unit 3, and the substrate 1 is held by the substrate holding stand 10. Thereafter, the planarization process is performed as described above with reference to FIG. 1.

Next, a method of aligning the template 4 and the substrate 1 in the XY directions in the planarization apparatus 200 shown in FIG. 9 will be described. First, a state is made in which neither the substrate 1 nor the template 4 is placed on the substrate holding stand 10 and the substrate holding unit 2.

Next, the substrate 1 is extracted from the substrate storage unit, and the substrate 1 is held by the template holding unit 5 through the template transport unit 6. Thereafter, the template holding unit 5 is brought close to the substrate holding stand 10, and the substrate 1 is transferred to the substrate holding stand 10.

If the substrate 1 on the substrate holding stand 10 is acquired by the substrate transport unit 3, the substrate transport unit 3 is moved to the second station 202, and the substrate 1 is carried onto the substrate holding unit 2 and held thereon. The position of the substrate 1 on the substrate holding unit 2 is then specified by performing the movement of the substrate holding unit 2 in the XY directions and measurement performed by the measuring unit 11 multiple times.

Meanwhile, although the above description has been made using the substrate 1 as a plate for specifying positional shift, there is no limitation thereto, and the series of steps described above may be performed using the template 4. That is, the position of the template 4 may be measured after the template 4 is carried into the template holding unit 5 by the template transport unit 6 and this template 4 is transferred to the substrate holding stand 10.

The difference between the position of the substrate 1 on the substrate holding unit 2 of the second station 202 specified above and the reference position is equivalent to the positional shift of the template 4 in the XY directions with respect to the substrate 1 when the template 4 and the substrate 1 are brought into contact with each other at the first station 201 to perform the planarization process.

Therefore, by adjusting the XY position of the template transport unit 6 when the template 4 is attached to the template holding unit 5 to a position where the above positional shift is eliminated, the template 4 on the template holding unit 5 can be held at a correct position (a position that matches the XY position of the substrate 1 during planarization).

Alternatively, the XY positions of the template 4 and the substrate 1 during the planarization process may be aligned by adjusting the XY position of the substrate transport unit 3 when the substrate 1 is held by the substrate holding stand 10 and correcting the XY position of the substrate 1 on the substrate holding stand 10.

The above reference position, that is, the reference position for obtaining the positional shift of the substrate 1 or the template 4 transported and transferred from the template holding unit 5 of the first station 201 to the substrate holding unit 2 of the second station 202, is determined using the second station 202.

The method of determining the reference position includes carrying the substrate 1 from the substrate transport unit 9 to the substrate holding unit 2 of the second station 202 and holding it, and specifying the XY position of the substrate 1 held by the substrate holding unit 2 through the XY movement of the substrate holding unit 2 and measurement performed by the measuring unit 11. The XY position of the substrate 1 specified here serves as the reference position.

According to the above, even if the configuration is divided into the first station 201 for performing the planarization process and the second station 202 for applying the curable composition onto the substrate 1, it is possible to improve the accuracy of superimposition when the template and the curable composition on the substrate are brought into contact with each other.

### <Embodiment of Article Manufacturing Method>

Next, a method of manufacturing an article (such as a semiconductor IC element, a liquid crystal display element, a color filter, or an MEMS) using the above-described planarization apparatus will be described. The manufacturing method includes a step of planarization a composition by bringing the composition disposed on a substrate (such as a wafer or a glass substrate) into contact with the mold using the above-described planarization apparatus, a step of curing the composition, and a step of releasing the composition and the mold.

This causes a planar film to be formed on the substrate. An article is manufactured by performing a process such as forming a pattern on a substrate having a planar film formed thereon using a lithography device, and processing the processed substrate in other well-known processing steps. Other well-known steps include etching, resist stripping, dicing, bonding, packaging, and the like. According to the present manufacturing method, it is possible to manufacture an article of higher quality articles than before.

### OTHER EMBODIMENTS

Hereinbefore, the planarization apparatus and the planarization method to which the embodiments according to the present invention are applied have been described above. According to the above embodiments, it is possible to align the positions of the substrate and the template in the XY directions (positions in the plane direction) when the substrate and the template are brought into contact with each other and the curable composition on the substrate is planarized, and to provide a planarization apparatus capable of planarization the entire surface of the substrate over its outer circumferential portion.

In addition, methods of aligning the positions of the substrate and the template in the XY directions (positions in the plane direction) during the planarization process have been described individually using a plurality of methods and a plurality of planarization apparatuses, but they may be used in combination as necessary without being limited to any one of them. The present invention is not limited to these embodiments, and various modifications and changes are possible without departing from the scope of the gist.

While the present invention has been described with reference to exemplary embodiments, it is to be understood that the invention is not limited to the disclosed exemplary embodiments. The scope of the following claims is to be accorded the broadest interpretation to encompass all such modifications and equivalent structures and functions.

In addition, as a part or the whole of the control according to the embodiments, a computer program realizing the function of the embodiments described above may be supplied to the planarization apparatus and the like through a network or various storage media. Then, a computer (or a CPU, an MPU, or the like) of the planarization apparatus and the like may be configured to read and execute the program. In such a case, the program and the storage medium storing the program configure the present invention.

In addition, the present invention includes those realized using at least one processor or circuit configured to perform functions of the embodiments explained above. For example, a plurality of processors may be used for distribution processing to perform functions of the embodiments explained above.

This application claims the benefit of priority from Japanese Patent Application No. 2023-099383, filed on Jun. 16, 2023, which is hereby incorporated by reference herein in its entirety.

What is claimed is:

1. A planarization apparatus configured to perform a planarization process of forming a planar layer on a substrate by bringing a planar surface of a template into contact with a curable composition on the substrate and then curing the curable composition, the apparatus comprising:
a transport unit configured to transport the substrate or the template;
a first holding unit configured to hold the substrate or the template transported by the transport unit;
a second holding unit configured to receive the substrate or the template held by the first holding unit from the first holding unit; and
a measuring unit configured to measure a position of the substrate or the template held by the second holding unit in a plane direction,
wherein the measuring unit obtains an amount of positional shift of the position from a reference position.

2. The planarization apparatus according to claim 1, wherein the first holding unit includes a template holding unit that holds the template in the planarization process, and
the second holding unit includes a substrate holding unit that holds the substrate in the planarization process.

3. The planarization apparatus according to claim 1, wherein the first holding unit includes a substrate holding unit that holds the substrate in the planarization process, and
the second holding unit includes a template holding unit that holds the template in the planarization process.

4. The planarization apparatus according to claim 2, wherein an adjustment of a position of at least one of the template holding unit, the substrate holding unit, the template held by the template holding unit, and the substrate held by the substrate holding unit in the plane direction is performed in the planarization process on the basis of the amount of positional shift.

5. The planarization apparatus according to claim 4, wherein the adjustment is performed so that the template and the substrate are aligned in the plane direction before the planar surface of the template is brought into contact with the surface of the substrate to which the curable composition is applied.

6. The planarization apparatus according to claim 4, further comprising a template transport unit configured to transport the template in the planarization process,
wherein an adjustment of the position of the template held by the template holding unit in the plane direction in the planarization process is performed by adjusting the position of the template transport unit in the plane direction when the template is held by the template holding unit from the template transport unit.

7. The planarization apparatus according to claim 4, wherein, in a case in which the planarization process is performed on a plurality of the substrates under the same conditions, the amount of positional shift is measured before the planarization process is performed on a first substrate that undergoes the planarization process as a first one of the plurality of substrates.

8. The planarization apparatus according to claim 2, wherein the reference position is a position of the substrate held by the substrate holding unit in the plane direction which is measured using the measuring unit after the substrate is transported to the substrate holding unit in the planarization process.

9. The planarization apparatus according to claim 3, wherein the reference position is a position of the template held by the template holding unit in the plane direction which is measured using the measuring unit after the template is transported to the template holding unit in the planarization process.

10. The planarization apparatus according to claim 2, wherein the measuring unit measures the position of the template held by the template holding unit in the plane direction, and
the measuring unit measures, in the planarization process, the position of the template in the plane direction when the template holding unit holding the template and the substrate holding unit are located at a longer distance than a predetermined distance and the position of the template in the plane direction when the template holding unit holding the template and the substrate holding unit are located at a shorter distance than the predetermined distance, and further obtains an amount of positional shift of the template holding unit in the plane direction when the template and the curable composition on the substrate are brought into contact with each other.

11. The planarization apparatus according to claim 2, wherein a difference between the amount of positional shift of the substrate or the template transferred from the template holding unit to the substrate holding unit and the amount of positional shift of the template holding unit when the template holding unit is moved closer to the substrate holding unit is obtained, the position in the plane direction when the template is attached to the template holding unit is adjusted using the difference, and the position of the substrate holding unit in the plane direction when the template and the substrate are brought into contact with each other is adjusted using the amount of positional shift of the template holding unit, and
the reference position is a position of the template held by the template holding unit in the plane direction which is measured using the measuring unit after the template is transported to the template holding unit in the planarization process.

12. A planarization apparatus configured to perform a planarization process of forming a planar layer on a substrate by bringing a planar surface of a template into contact with curable composition on the substrate and then curing the curable composition, the apparatus comprising:
a template holding unit configured to hold the template;
a substrate holding unit configured to hold the substrate;
a measuring unit configured to measure a position of the template in a plane direction; and
at least one processor or circuit configured to function as:
a control unit configured to obtain an amount of positional shift from a reference position of the position of the template measured by the measuring unit and control the template holding unit and the substrate holding unit on the basis of the amount of positional shift,
wherein the control unit corrects the positional shift by moving the substrate holding unit to a first position for receiving the template from the template holding unit, transferring the template from the template holding unit to the substrate holding unit, moving the substrate holding unit to a second position for transferring the template to the template holding unit, and transferring the template held by the substrate holding unit to the template holding unit.

13. The planarization apparatus according to claim 12, wherein the measuring unit measures the position of the template held by the template holding unit in the plane direction,
the first position is a position where the position of the template held by the template holding unit in the plane direction matches the substrate holding unit, and
the second position is a position where the position of the template held by the substrate holding unit in the plane direction matches the reference position of the template.

14. The planarization apparatus according to claim 13, wherein the reference position is the position of the template held by the template holding unit in the plane direction which is measured using the measuring unit after the template is held by the template holding unit and before the template is used for the planarization process, or the position of the substrate on the template holding unit in the plane direction which is measured using the measuring unit after the substrate on the substrate holding unit is transferred to the template holding unit in a state where the template is not held by the template holding unit.

15. The planarization apparatus according to claim 12, wherein the measuring unit measures the position of the template held by the substrate holding unit in the plane direction,
the first position is a position where the template holding unit and the substrate holding unit are aligned, and
the second position is a position where the position of the template held by the substrate holding unit in the plane direction matches the reference position.

16. The planarization apparatus according to claim 15, wherein the reference position is the position of the substrate on the substrate holding unit in the plane direction which is measured using the measuring unit after the substrate is held by the substrate holding unit and before the planarization process is performed on the substrate, or the position of the template on the substrate holding unit in the plane direction which is measured using the measuring unit after the template is held by the template holding unit and the template is transferred to the substrate holding unit in a state where the substrate is not held by the substrate holding unit.

17. A planarization method for performing a planarization process of forming a planar layer on a substrate by bringing a planar surface of a template into contact with curable composition on the substrate and then curing the curable composition, the method comprising:
transporting the substrate or the template;
holding the transported substrate or template by a first holding unit;
transferring the substrate or the template held by the first holding unit from the first holding unit to a second holding unit;
measuring a position of the substrate or the template held by the second holding unit in a plane direction; and
obtaining an amount of positional shift from a reference position of the measured position.

18. A planarization method for performing a planarization process of forming a planar layer on a substrate by bringing a planar surface of a template into contact with curable composition on the substrate and then curing the curable composition, the method comprising:
holding the template by a template holding unit;
holding the substrate by a substrate holding unit;
measuring a position of the template in a plane direction; and
obtaining an amount of positional shift from a reference position of the measured position of the template and controlling the template holding unit and the substrate holding unit on the basis of the amount of positional shift,
wherein the controlling includes correcting the positional shift by moving the substrate holding unit to a first position for receiving the template from the template holding unit, transferring the template from the template holding unit to the substrate holding unit, moving the substrate holding unit to a second position for transferring the template to the template holding unit, and transferring the template held by the substrate holding unit to the template holding unit.

19. An article manufacturing method of manufacturing an article using a planarization method for performing a planarization process of forming a planar layer on a substrate by bringing a planar surface of a template into contact with a curable composition on the substrate and then curing the curable composition,
wherein the planarization method includes
transporting the substrate or the template,
holding the transported substrate or template by a first holding unit,
transferring the substrate or the template held by the first holding unit from the first holding unit to a second holding unit,
measuring a position of the substrate or the template held by the second holding unit in a plane direction,
obtaining an amount of positional shift from a reference position of the measured position to form a planar film on the substrate using the planarization method, and
processing the substrate on which the planar film is formed to manufacture an article from the processed substrate.
